(19) United States
(12) Patent Application Publication
(10) Pub. No.: US 2018/0069035 A1
(43) Pub. Date: Mar. 8, 2018

(54) Tensile Contact Etch Stop Layer (CESL) For Radio Frequency (RF) Silicon-On-Insulator (SOI) Switch Technology

(71) Applicant: Newport Fab, LLC dba Jazz Semiconductor, Inc., Newport Beach, CA (US)

(72) Inventor: Paul D. Hurwitz, Irvine, CA (US)

(21) Appl. No.: 15/256,278

(22) Filed: Sep. 2, 2016

(51) Int. Cl. H01L 27/13; H01L 29/78; H01L 29/45; H01L 21/02; H01L 21/322

(52) U.S. Cl. CPC H01L 27/13; H01L 29/7843; H01L 29/458; H01L 21/0217; H01L 29/78621; H01L 21/3226; H01L 21/02274; H01L 21/02211; H01L 21/02359

(57) ABSTRACT

A radio frequency switch includes a plurality of n-channel SOI CMOS transistors connected in series, wherein each of these transistors has a gate width of at least about 0.13 microns. A contact etch stop layer (CESL) structure having a relatively large thickness of at least about 1000 Angstroms is formed on silicide regions of the n-channel SOI CMOS transistors, wherein the CESL structure places a tensile stress on channel regions of the n-channel SOI CMOS transistors, thereby reducing the on-resistances of the n-channel SOI CMOS transistors. The CESL structure is also formed over p-channel SOI CMOS transistors fabricated on the same substrate as the n-channel SOI CMOS transistors. While the CESL structure also places a tensile stress on channel regions of the p-channel SOI CMOS transistors (increasing the on-resistances of these transistors), the on-resistances of the p-channel SOI CMOS transistors are non-critical in the RF switch application.

### FIELD OF THE INVENTION

The present invention relates to the use of a contact etch stop layer (CESL) to introduce tensile stress to the channel regions of silicon-on-insulator (SOI) CMOS transistors used in high power applications such as radio frequency (RF) switching.

### RELATED ART

FIG. 1 is a circuit diagram of a conventional radio frequency (RF) circuit 100, including an antenna 101, an RF receiver switch 110, an RF receiver port 115, an RF transmitter switch 120 and an RF transmitter port 125. RF receiver switch 110 includes a plurality of high-voltage field effect transistors (FETs) 110₁-110_{N}, which are connected in series (in a stack). The stack of high voltage FETs 110₁-110_{N} is controlled to route RF signals from antenna 101 to receive port 115. Similarly, RF transmitter switch 120 includes a stack of high-voltage FETs 120₁-120_{N}, which are controlled to route RF signals from transmit port 125 to antenna 101. As used herein, an RF signal is defined as a signal having a frequency in the range of about 10 kHz to 50 GHz.

Silicon-on-insulator (SOI) CMOS technologies are now the dominant platforms for creating best-in-class radio frequency switch (RFSW) products for handsets and other mobile devices. Thus, transistors 110₁-110_{N} and 120₁-120_{N} are typically implemented using SOI CMOS transistors. Such SOI CMOS transistors enable the associated RF switches 110 and 120 to transmit RF signals in the range of 0.5 GHz to 6 GHz with a high degree of linearity, while withstanding voltages of 40V to 70V and in off-state. Because SOI CMOS technology uses standard CMOS technologies and standard cell libraries, RF switches that implement SOI CMOS transistors can be readily integrated into larger system-on-chip (SOC) devices, thereby further minimizing fabrication costs.

Transistors 110₁-110_{N} and 120₁-120_{N}, RF receiver port 115 and RF transmitter port 125 are typically fabricated on the same semiconductor substrate. Transistors 110₁-110_{N} and 120₁-120_{N} are typically n-channel SOI CMOS transistors. RF receiver port 115 and RF transmitter port 125 include low-speed logic and analog circuitry which are constructed using both n-channel and p-channel SOI CMOS transistors (not shown).

For an RF switch, the on-resistance of the switch (R_{ON}) multiplied by the off-capacitance of the switch (C_{OFF}) is a key figure of merit, which dictates the ability to transmit RF power with low losses through on-state stacks, while maintaining adequate isolation across off-state stacks. Typically these off-state stacks need to hold off relatively high voltage RF signals (e.g., 40-70V). Consequently, RF switches are implemented with older generation SOI CMOS transistors having operating voltages in the 2.5 Volt-5 Volt range (and even higher breakdown voltages). These older generation SOI CMOS transistors are fabricated using processes with a minimum feature size of 0.13 microns or greater. In general, the gate length of each of transistors 110₁-110_{N} and 120₁-120_{N} must be about 0.2 microns or more to provide the required off-state isolation.

Thin film SOI CMOS transistors are attractive for RF switch applications, because these transistors reduce the junction capacitance component of the off-capacitance value, C_{OFF}. In order to further minimize the R_{ON}*C_{OFF} value, it is desirable for the on-resistances of the SOI CMOS transistors 110₁-110_{N} and 120₁-120_{N} to be as low as possible. However, traditional CMOS scaling is not an acceptable path for on-resistance reduction in this application, because such scaling would prevent the resulting transistors from meeting the required operating voltages and power handling requirements. That is, while transistors having channel lengths of less than about 0.13 microns would advantageously exhibit low on-resistances, such transistors would not be able to handle the operating voltages (or power requirements) associated with an RF switch application. Moreover, it would not be cost effective to use SOI CMOS transistors fabricated using advanced deep sub-micron processes (e.g. processes having minimum features sizes of 90 nm or less) in an RF switch application, because of the higher fabrication costs associated with technologies having smaller feature sizes.

Traditional process technologies having a minimum feature size of about 0.25 microns (and transistor operating voltages of about 2.5 Volts) have used the various means for reducing the on-resistances of N-channel SOI CMOS transistors, while maintaining adequate (RF) breakdown voltages. For example, lightly doped drain (LDD) implants in the range of about 1 E14 to 1 E15 ions/cm² have been used to minimize extrinsic resistance subject to the breakdown voltage constraints of the application. Silicon nitride sidewall spacer materials have been used to allow the widths of the sidewall spacers of the transistors to be reduced, thereby reducing the widths of the LDD regions (and thereby reducing the on-resistances of the transistors). Note that thin oxide sidewall spacers do not provide an adequate process margin, as they are eroded by the wet etches used in the front end of line (FEOL) process. Halo implants have also been implemented to reduce short-channel effects, allowing scaling to smaller gate lengths (which result in lower channel resistances). While these solutions result in lower transistor on-resistances, it would be desirable to have further methods for reducing the on-resistances of SOI CMOS transistors for use in RF switches.

It would therefore be desirable to have an improved SOI CMOS transistor for implementing RF switches, wherein said SOI CMOS transistor exhibits a reduced on-resistance, thereby providing a lower R_{ON}*C_{OFF} value than previously available. It would further be desirable if this improved SOI CMOS transistor could be easily fabricated, with only slight variations from a conventional SOI CMOS process. It would further be desirable for this improved SOI CMOS transistor to be capable of handling the voltage and power requirements of RF switching applications.

### SUMMARY

Accordingly, the present invention provides an RF switch that includes a plurality of series-connected n-channel SOI CMOS transistors fabricated in accordance with a 0.13 micron (or greater) process, wherein a contact etch stop layer (CESL) formed over the n-channel SOI CMOS transistors imposes a substantial tensile stress on the p-type channel regions of these transistors, thereby reducing the on-resistances of these transistors. In one embodiment, the CESL has a thickness of about 1000 Angstroms or more. In one embodiment, the CESL is subjected to one or more high temperature anneals, which cause the CESL to contract, thereby introducing tensile stress to the channel regions of the SOI CMOS transistors. Each SOI CMOS transistor may have a gate length of at least about 0.13 microns to provide operating/breakdown voltages acceptable for use in an RF switch, and to enable the SOI CMOS transistor to handle the power requirements of the RF switch. In a particular embodiment, the CESL may be fabricated by the deposition of one or more layers of silicon nitride.

In one embodiment, the CESL is formed over both re-channel SOI CMOS transistors (including the RF switch transistors) and p-channel SOI CMOS transistors fabricated on the same substrate. Because the same CESL structure is formed over both the n-channel and p-channel transistors, the fabrication process is simplified. While the on-resistances of the n-channel SOI CMOS transistors are reduced (thereby advantageously reducing the on-resistance R_{ON} of the RF switch), the on-resistances of the p-channel SOI CMOS transistors are increased. However, because the p-channel transistors are only used in non-critical logic or analog circuitry in the RF switch application, the increase in the on-resistances of the p-channel transistors is acceptable.

Another embodiment includes methods for fabricating the SOI CMOS transistor of the present invention. One method includes forming a plurality of SOI CMOS transistors, including a plurality of series-connected transistors of an RF switch, on a thin silicon layer. In one embodiment, each of the transistors includes a gate having a gate length of at least about 0.13 microns, source/drain regions, LDD regions, halo implant regions, and silicon nitride sidewall spacers formed adjacent to the gate. Metal silicide regions are formed on the gate and the source/drain regions. The CESL is deposited over the plurality of transistors. In one embodiment, the CESL is formed of one or more layers of silicon nitride, which are deposited to a thickness of at least about 1000 Angstroms. In one embodiment, the silicon nitride is formed by a chemical vapor deposition process using silane and ammonia. One or more high temperature anneals can be performed to remove hydrogen from the silicon nitride layer, thereby causing the silicon nitride layer to shrink. The shrinking silicon nitride layer introduces tensile stresses to the channel regions of the SOI CMOS transistors, thereby resulting in a reduction of the on-resistances of the n-channel transistors.

The present invention will be more fully understood in view of the following description and drawings.

### BRIEF DESCRIPTION OF THE DRAWINGS

FIG. 1 is a circuit diagram of a conventional radio frequency (RF) circuit, including a pair of RF switches.

FIG. 2 is a cross-sectional view of an SOI CMOS structure, which includes n-channel SOI CMOS transistors and a p-channel SOI CMOS transistor.

FIGS. 3A-3C are cross sectional views of the semiconductor structure of FIG. 2 during the formation of a pre-metal dielectric structure, including a contact etch stop layer (CESL) structure, in accordance with one embodiment of the present invention.

FIG. 4 is a cross sectional view of the semiconductor structure of FIG. 2 during the formation of a CESL structure, in accordance with an alternate embodiment of the present invention.

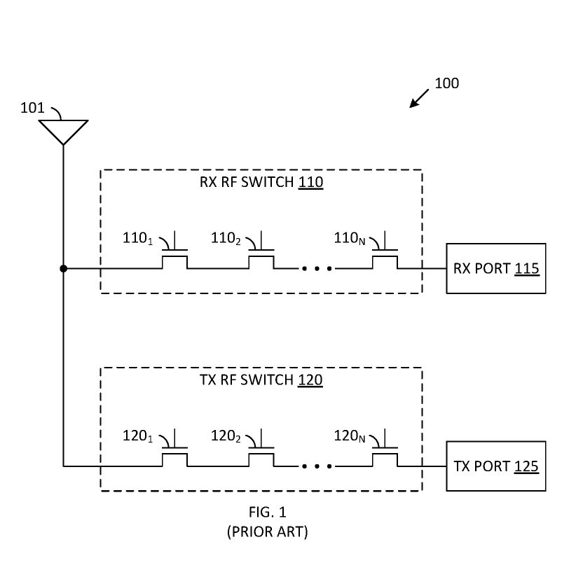

### DETAILED DESCRIPTION

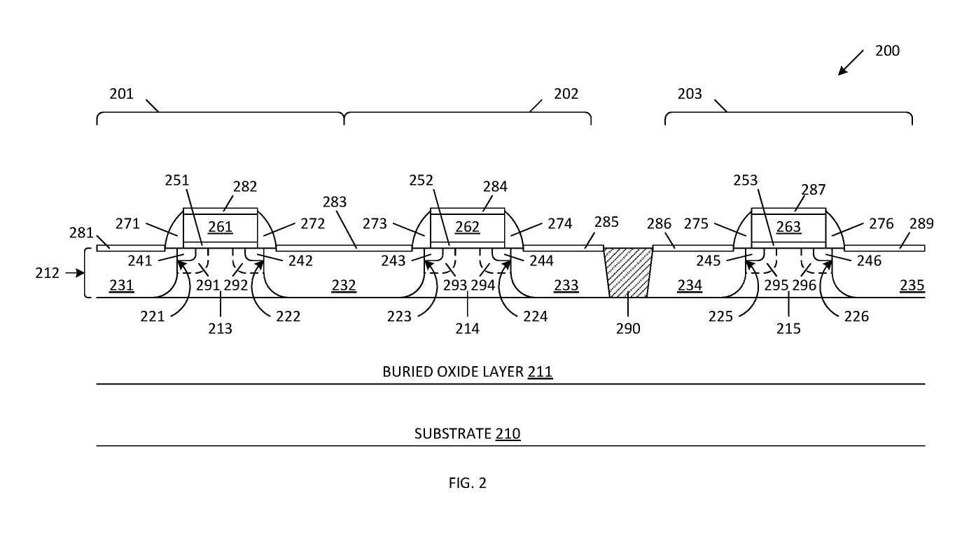

FIG. 2 is a cross-sectional view of an SOI CMOS structure 200, which includes n-channel SOI CMOS transistors 201-202 and p-channel SOI CMOS transistor 203. In accordance with one embodiment, transistors 201-202 may represent series-connected transistors of an RF switch. For example, transistors such as transistors 201-202 may be used to replace the series-connected transistors 110₁-110_{N} of the receiver RF switch 110 (and the series-connected transistors 120₁-120_{N} of the transmitter RF switch 120) in one embodiment of the present invention. In this embodiment, transistors having the construction of transistors 201-203 are also used to implement non-critical logic and analog circuitry that supports these RF switches (e.g., logic and circuitry in the RF receiver port 115 and the RF transmit port 125). SOI CMOS transistors 201-203 are fabricated on a thin silicon layer 212, which is located on a buried insulator layer 211 (e.g., silicon oxide), which in turn, is located on a substrate 210 (e.g., monocrystalline silicon). In accordance with one embodiment, thin silicon layer 212 has a thickness in the range of about 300 to 1500 Angstroms.

N-channel SOI CMOS transistor 201 includes an n-type source region 221 (which includes an N+ source contact region 231 and an N− lightly doped source region 241), an n-type drain region 222 (which includes N+ drain contact region 232 and N− lightly doped drain region 242), gate dielectric 251, polysilicon gate 261, dielectric (silicon nitride) sidewall spacers 271-272 and metal silicide regions 281-283. A p-type channel region 213 exists between the source region 221 and the drain region 222. Optional p-type halo regions 291-292 are included in p-type channel region 213.

N-channel SOI CMOS transistor 202 includes an n-type source region 223 (which includes shared N+ source contact region 232 and an N− lightly doped source region 243), an n-type drain region 224 (which includes N+ drain contact region 233 and N− lightly doped drain region 244), gate dielectric 252, polysilicon gate 262, dielectric (silicon nitride) sidewall spacers 273-274 and metal silicide regions 283-285. A p-type channel region 214 exists between the source region 223 and the drain region 224. Optional p-type halo regions 293-294 are included in p-type channel region 214.

P-channel SOI CMOS transistor 203 includes a p-type source region 225 (which includes P+ source contact region 234 and P— lightly doped source region 245), a p-type drain region 226 (which includes P+ drain contact region 235 and P— lightly doped drain region 246), gate dielectric 253, polysilicon gate 263, dielectric (silicon nitride) sidewall spacers 275-276 and metal silicide regions 286-289. An n-type channel region 215 exists between the source region 225 and the drain region 226. Optional n-type halo regions 295-296 are included in n-type channel region 215. Shallow trench isolation region 290 electrically isolates p-channel transistor 203 from n-channel transistors 201-202.

Fabrication of the transistors 201-203 is implemented by conventional front end of line (FEOL) processing. In the described embodiments, transistors 201-203 are fabricated with a process having a minimum feature size of 0.13 microns or greater, such that transistors 201-203 have gate lengths of at least 0.13 microns, and operating voltages of 2.5 Volts or more. In a particular embodiment, transistors 201-203 are fabricated with a process having a minimum feature size of 0.25 microns, such that each of the transistors 201-203 have a gate length of at least 0.25 microns. Note that the conventional silicon nitride sidewall spacers 271-276, halo implants 291-296 and LDD regions 241-246 all contribute to reduce the on-resistances of transistors 201-203 in the manner described above.

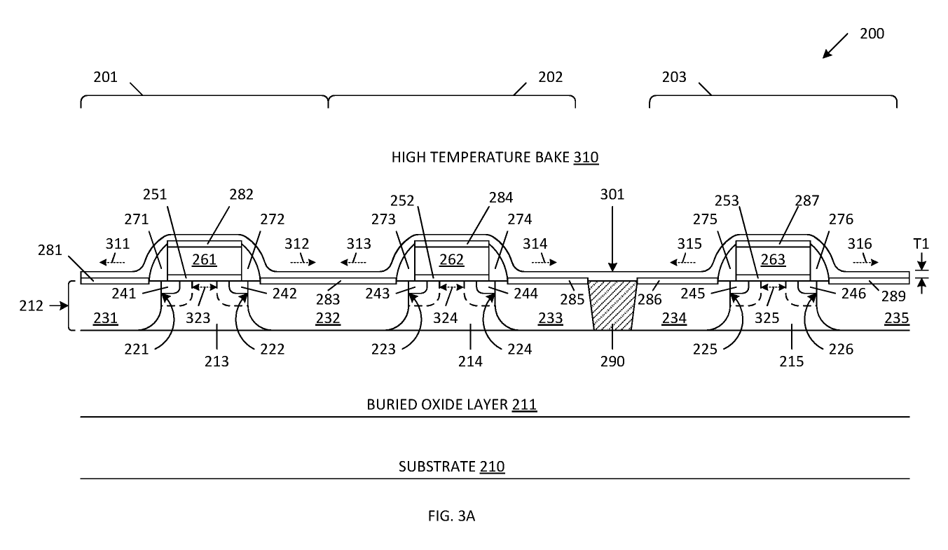

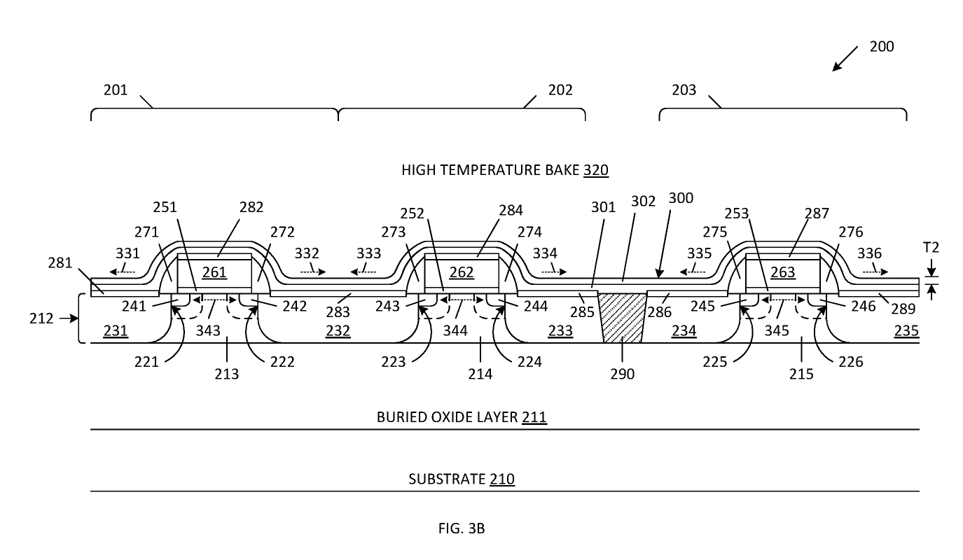

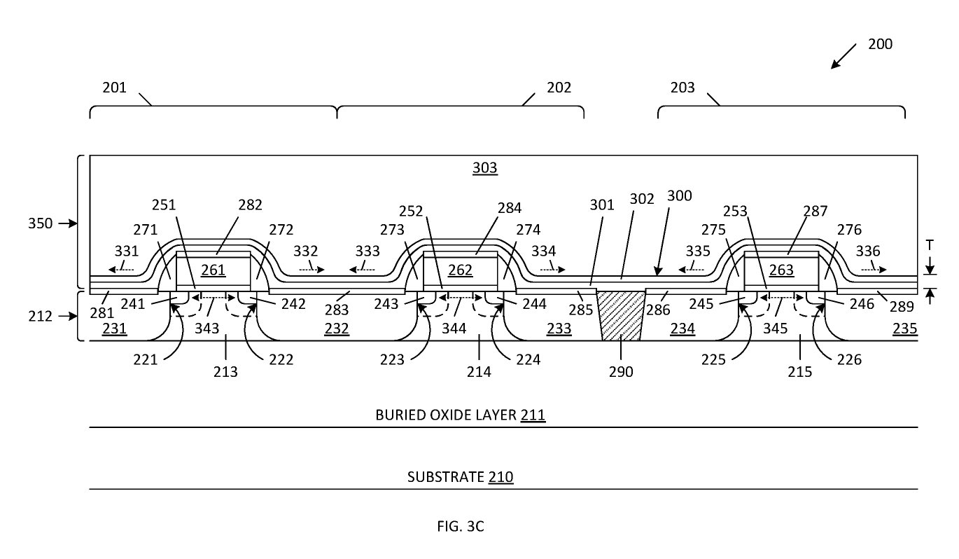

FIGS. 3A-3C are cross sectional views of the semiconductor structure 200 (FIG. 2) during the formation of a pre-metal dielectric structure 350 in accordance with one embodiment of the present invention. As illustrated by FIGS. 3A-3C, a thick contact etch stop layer (CESL) structure 300 having a thickness of at least about 1000 Angstroms is fabricated over the SOI CMOS structure 200 of FIG. 2. The formation of CESL structure 300 occurs after the formation of metal silicide regions 281-289, as the first step in a pre-metal dielectric module. The thickness of CESL structure 300 is at least about three times thicker than a conventional CESL structure used by the process used to fabricate transistors 201-203. For example, silicon processing technologies used to fabricate SOI CMOS transistors 201-203 having the required feature sizes (0.13 microns and up) and operating voltages (2.5 Volts and up) typically use a CESL structure having a total thickness of no more than about 300 Angstroms.

In accordance with one embodiment, CESL structure 300 is silicon nitride (Si₃N₄), formed by a plasma enhanced chemical vapor deposition (PECVD) process that uses silane (SiH₄) and ammonia (NH₃) as the reactants. As described in more detail below, as CESL structure 300 is formed, a tensile stress is developed in this structure 300. As a result, the channel regions 213-215 of transistors 201-203 are placed under tensile stress, thereby lowering the on-resistances of n-channel SOI CMOS transistors 201-202 (and increasing the on-resistance of p-channel SOI CMOS transistor 203).

As illustrated in FIG. 3A, a first dielectric layer 301 is deposited over the semiconductor structure 200 of FIG. 2. In the described embodiment, the first dielectric layer 301 is silicon nitride, which is deposited to a thickness T1 in the range of about 350 to 650 Angstroms by introducing silane and ammonia at rates of 0.05 and 0.5 liters per minute (LPM), respectively, into a deposition chamber at a temperature of about 450° C. and a pressure of about 3T.

During the silicon nitride deposition process, some hydrogen is incorporated into the silicon nitride layer 301. After the silicon nitride layer 301 has been deposited, a high temperature bake 310 is performed. In one embodiment, the high temperature bake 310 is performed by heating to a temperature of about 650° C. for a duration of about one hour. The high temperature bake 310 initiates a chemical reaction that drives some of the hydrogen out of the silicon nitride layer 301, thereby creating unpaired (dangling) bonds within the silicon nitride material, which link up and become closed. Under these conditions, the silicon nitride layer 301 shrinks, thereby introducing stresses within the silicon nitride layer 301, which are indicated by arrows 311-316 in FIG. 3A. The stresses 311-316 in silicon nitride film 301 compress the underlying source/drain regions 231-235, thereby introducing tensile stresses to channel regions 213-215. The tensile stresses in channel regions 213-215 are represented by arrows 323-325, respectively in FIG. 3A.

As illustrated in FIG. 3B, a second dielectric layer 302 is deposited over the first dielectric layer 301. In the described embodiment, the second dielectric layer 302 is also silicon nitride, with thickness and deposition conditions comparable to the first layer 301.

Again, during the silicon nitride deposition process, some hydrogen is incorporated into silicon nitride layer 302. After the silicon nitride layer 302 has been deposited, a second high temperature bake 320 is performed. In one embodiment, the high temperature bake 320 is performed by heating to a temperature of about 650° C. for a duration of about one hour. The high temperature bake 320 drives hydrogen out of silicon nitride layer 302 (and possibly silicon nitride layer 301), thereby causing silicon nitride layer 302 (and possibly silicon nitride layer 301) to shrink in the manner described above, introducing stresses within silicon nitride layer 302, which are indicated by arrows 331-336 in FIG. 3B. The stresses 331-336 in silicon nitride layer 302 further compress the underlying source/drain regions 231-235, thereby introducing further tensile stresses to channel regions 213-215. The combined tensile stresses introduced to channel regions 213-215 by silicon nitride layers 301-302 are represented by arrows 343-345, respectively in FIG. 3B. Arrows 343-345 are larger than arrows 323-325 to represent larger tensile stresses in the channel regions 213-215. At the end of the second high temperature bake 320, the silicon nitride layers 301-302 combine to form a CESL structure 300 having a total thickness (T=T1+T2) of at least about 1000 Angstroms.

As illustrated in FIG. 3C, the main pre-metal dielectric structure 303 of the pre-metal dielectric module is fabricated over the CESL structure 300. In the described embodiment, the main pre-metal dielectric structure 303 includes about 6000 Angstroms of tetraethyl orthosilicate (TEOS)-based deposited oxide doped with boron and phosphorus. Other dielectric materials can be used to implement main pre-metal dielectric structure 303 in other embodiments. The main pre-metal dielectric structure 303 has a planar upper surface, as illustrated. Contacts to transistors 201-203 (and other circuit elements fabricated on silicon layer 212) are formed through the main pre-metal dielectric structure 303 and the CESL structure 300 in a manner known to those in the art. More specifically, an initial etch is performed through the main pre-metal dielectric structure 303, wherein the initial etch is stopped on CESL structure 300. Another etch is then performed through CESL structure 300, thereby exposing underlying regions to be contacted (e.g., metal silicide regions 281-289).

Although the embodiment of FIGS. 3A-3C includes a CESL structure 300 that includes two dielectric layers 301-302 and implements two associated high temperature bakes 310 and 320, it is understood that other numbers of dielectric layers and other numbers of high temperature bakes can be used in other embodiments. In one embodiment, the fabrication of CESL structure 300 is tuned (using, for example, higher silane-to-ammonia ratios and higher temperatures) to maximize the stress within CESL structure 300 as this CESL structure 300 is deposited.

The tensile stresses 343-344 introduced to the channel regions 213-214 of n-channel transistors 201-202 enhances electron mobility in these channel regions 213-214. That is, the tensile stresses 343-344 separate the energy bands/atoms in the channel regions 213-214, thereby making these channel regions less collisional. As a result, the on-resistances of n-channel transistors 201-202 are advantageously reduced. In particular embodiments, the on-resistances (R_{ON}) of n-channel transistors 201-202 are advantageously reduced by 15 to 20 percent, which translates directly into lower product insertion loss in the associated RF switch. Because of field-dependent effects and extrinsic resistance, the increase in the on-current (I_{ON}) of the re-channel transistors 201-202 due to the tensile stresses 343-344 is significantly smaller, for example, about 5 percent. Advantageously, the tensile stresses 343-344 do not introduce any associated penalty in the power handling capability of the n-channel transistors 201-202.

The on-current (I_{ON}) of a transistor is a critical figure of merit for digital applications. However, in an RF switch (e.g., RF switches 110 and 120), the on-resistance (R_{ON}) of the switching transistors is a far more important design parameter. The present invention advantageously provides a significant improvement in the on-resistances of RF switching transistors (e.g., n-channel transistors 201-202).

The lower on-resistance (and increased on-current) provided to the n-channel transistors 201-202 by the stressed CESL structure 300 is additive to the above-described means used to lower the on-resistance of these n-channel transistors 201-202. That is, the lower on-resistance resulting from the stressed CESL structure 300 is additive to the lower on-resistances resulting from the use of silicon nitride sidewall spacers 271-274, halo implants 291-294 and LDD regions 241-244.

P-channel SOI CMOS transistor 203 (as well as transistors similar to n-channel SOI CMOS transistors 201-202), are used to implement non-critical logic and analog circuitry in the RF switching circuit (e.g., circuitry in the RF receiver port 115 or the RF transmit port 125). In this RF switching application, performance of these p-channel transistors is not as important as the performance of the RF switching transistors. As described above, the same CESL structure 300 is formed over both the n-channel transistors 201-202 and the p-channel transistor 203. The CESL structure 300 increases the on-resistances of the p-channel transistor 203 by about 15 to 20 percent (i.e., about the same amount that the on-resistances of the n-channel transistors are reduced). However, the degraded performance of the p-channel transistor 203 is not significant in the RF switching application. Moreover, p-channel transistors (such as p-channel transistor 203) will only constitute a small percentage of the layout area of a chip that implements an RF switching application (because a large percentage of the layout area of the chip is used for the RF switches 110 and 120).

Note that in some advanced CMOS processes (e.g., processes having minimum line widths of 90 nm and below, stressed CESL structures have been used to enhance electron mobility in n-channel transistors. However, as described above, these stressed CESL structures degrade the performance of p-channel transistors. Because there is a need for balanced p-channel and n-channel transistors in these advanced CMOS processes, it is necessary to remove the stressed CESL structure over the p-channel transistors, or otherwise disrupt the stress exerted by the stressed CESL structure on the p-channel transistors. CESL structures used in advanced CMOS processes must be much thinner than 1000 Angstroms thick to support the aggressive design rules.

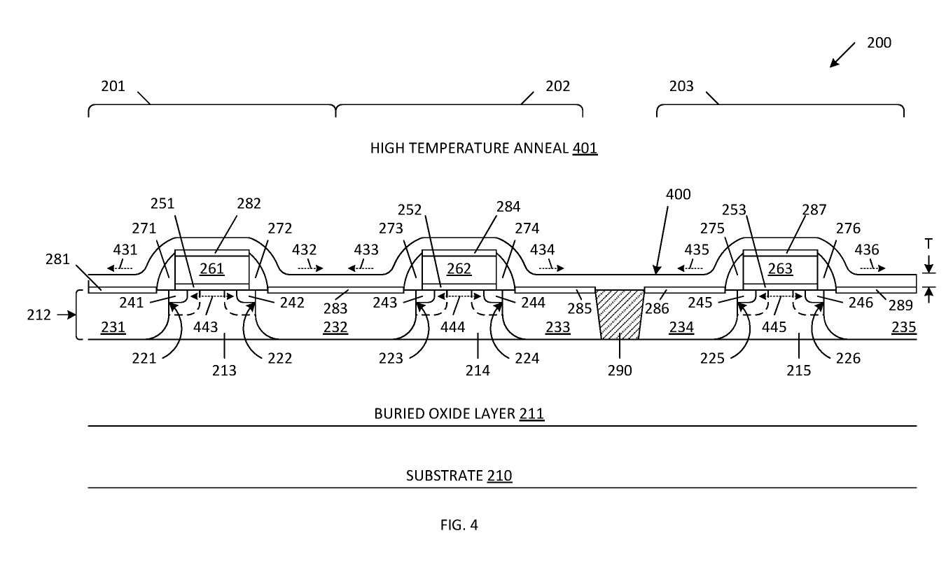

FIG. 4 is a cross sectional view of the semiconductor structure 200 (FIG. 2) during the formation of CESL structure 400 in accordance with an alternate embodiment of the present invention. As illustrated by FIG. 4, a thick CESL structure 400 having a thickness of at least about 1000 Angstroms is fabricated over the SOI CMOS structure 200 of FIG. 2. The CESL structure 400 is deposited as a single layer, which is subsequently annealed. In one embodiment, CESL structure 400 is a single layer of silicon nitride, formed by a plasma enhanced chemical vapor deposition (PECVD) process that uses silane (SiH₄) and ammonia (NH₃) as reactants. CESL structure 400 can be deposited to a thickness of at least about 1000 Angstroms by introducing silane and ammonia at rates of about 0.02 standard liters per minute (SLM) and 0.05 SLM, respectively, into a deposition chamber at a temperature of about 500° C. and a pressure of about 5T.

Under such deposition conditions no additional annealing is needed to achieve adequate tensile stresses within CESL structure 400, which are indicated by arrows 431-436 in FIG. 4. The stresses 431-436 in CESL structure 400 compress the underlying source/drain regions 231-235, thereby introducing tensile stresses 443-445 to channel regions 213-215, respectively. As a result, the on-resistances of re-channel transistors 201-202 are reduced (and the on-resistance of p-channel transistor 203 is increased) in the manner described above in connection with FIGS. 3A-3C. A pre-metal dielectric layer, similar to pre-metal dielectric layer 303, is then formed over CESL structure 400 to complete the pre-metal dielectric structure.

Although the invention has been described in connection with several embodiments, it is understood that this invention is not limited to the embodiments disclosed, but is capable of various modifications, which would be apparent to a person skilled in the art. Thus, the invention is limited only by the following claims.

We claim:

1. A semiconductor circuit comprising:
a plurality of n-channel transistors fabricated on a semiconductor substrate, wherein the plurality of re-channel transistors are connected in series to form a radio frequency switch;
one or more p-channel transistors fabricated on the semiconductor substrate; and
a contact etch stop layer (CESL) structure located on the n-channel transistors and the p-channel transistors, wherein the CESL structure has a thickness of at least about 1000 Angstroms.

2. The semiconductor circuit of claim 1, wherein the CESL structure comprises silicon nitride.

3. The semiconductor circuit of claim 1, wherein the re-channel transistors and the p-channel transistors each have a gate with a length of at least about 0.13 microns.

4. The semiconductor circuit of claim 1, wherein the semiconductor substrate comprises a silicon layer formed over a buried oxide layer.

5. The semiconductor circuit of claim 4, wherein the silicon layer has a thickness of about 300 to 1500 microns.

6. The semiconductor circuit of claim 1, further comprising a pre-metal dielectric layer located on the CESL structure.

7. The semiconductor circuit of claim 1, wherein the pre-metal dielectric layer comprises a deposited oxide.

8. The semiconductor circuit of claim 1, wherein the CESL structure contacts silicide regions of the n-channel transistors and the p-channel transistors.

9. The semiconductor circuit of claim 1, wherein the CESL structure includes a plurality of silicon nitride layers.

10. The semiconductor circuit of claim 1, wherein the CESL structure applies tensile stresses to channel regions of the n-channel transistors and the p-channel transistors.

11. The semiconductor circuit of claim 1, wherein the re-channel transistors include silicon nitride sidewall spacers.

12. The semiconductor circuit of claim 1, wherein the re-channel transistors include halo implants.

13. The semiconductor circuit of claim 1, wherein the re-channel transistors include lightly doped drain regions.

14. A method for fabricating a semiconductor structure comprising:
depositing a contact etch stop layer (CESL) structure on silicide regions of a plurality of transistors;
annealing the CESL structure, thereby introducing tensile stress to channel regions of the plurality of transistors; and then
depositing a pre-metal dielectric layer over the CESL structure.

15. The method of claim 14, wherein the CESL structure is deposited in two or more layers, wherein an anneal is performed after depositing each of the two or more layers.

16. The method of claim 14, further comprising depositing the CESL structure to a thickness of at least about 1000 Angstroms.

17. The method of claim 14, wherein the CESL structure comprises silicon nitride.

18. The method of claim 18, wherein the plurality of transistors include both n-channel transistors and p-channel transistors.

19. The method of claim 14, further comprising forming lightly doped drain (LDD) regions in the plurality of transistors.

20. The method of claim 14, further comprising forming halo implant regions in the plurality of transistors.

21. The method of claim 14, further comprising forming silicon nitride sidewall spacers adjacent to gates of the plurality of transistors.
